(19) United States
(12) Patent Application Publication
(10) Pub. No.: US 2026/0229462 A1
(43) Pub. Date: Aug. 6, 2026

(54) SYSTEMS AND METHODS FOR CONTROLLING FAST ACTUATORS IN AN IMPEDANCE MATCHING UNIT

(71) Applicant: Lam Research Corporation, Fremont, CA (US)

(72) Inventors: Neil Martin Paul Benjamin, Palo Alto, CA (US); Lee Chen, Cedar Creek, TX (US); Hema Swaroop Mopidevi, Georgetown, TX (US)

(21) Appl. No.: 19/149,830

(22) PCT Filed: Jan. 18, 2024
(86) PCT No.: PCT/US2024/012080

§ 371 Date: Jul. 21, 2025

Related U.S. Application Data
(60) Provisional application No. 63/441,164, filed on Jan. 25, 2023.

(51) Int. Cl. H01J 37/32; H03H 7/40

(52) U.S. Cl. CPC H01J 37/32183; H01J 37/32935; H03H 7/40

(57) ABSTRACT

Systems and methods for controlling fast actuators in an impedance matching unit are described. The impedance matching unit includes an input port coupled to a radio frequency (RF) generator. The impedance matching unit further includes an output port coupled to a plasma chamber. The impedance matching unit includes a connection point located between the input port and the output port, a first reactive element coupled between the input port and the connection point, and a first switch coupled in parallel to the first reactive element. The impedance matching unit includes a second reactive element coupled between the connection point and the output port, and includes a second switch coupled in parallel to the second reactive element.

### FIELD

The present embodiments relate to systems and methods for controlling fast actuators in an impedance matching unit.

### BACKGROUND

A semiconductor device is fabricated using plasma processing. The plasma processing involves introducing radio frequency (RF) to energize gas molecules of a gas mixture to form plasma. The plasma is contained in a partial vacuum chamber, referred to as a processing chamber, and the RF energy is introduced into the processing chamber through antennas and/or electrodes.

In a plasma process, an RF generator supplies power at a radio frequency, and this power is generally transmitted via an RF cable, typically having an impedance of 50 Ohms. To match impedances, such as a load impedance of the processing chamber and a source impedance of the RF generator, an RF matching network is placed between the RF generator and the processing chamber. A semiconductor wafer is placed in the processing chamber for being processed with the RF energy. To provide efficient transfer of power from the RF generator to the processing chamber, the RF matching network is used to match a variable impedance of the processing chamber with a fixed impedance of the RF generator.

The purpose of the RF matching network is to transform the load impedance presented by the processing chamber containing the plasma to a value that will absorb RF power before being reflected towards the RF generator. This does not require an exact 50 Ohm match but to the extent there is mismatch between the source and load impedances, some portion of the RF power is reflected back towards the RF generator. In many cases, particularly in semiconductor fabrication processes, an impedance of the RF generator is fixed at 50 Ohms, and RF power is transmitted through the RF cable, which also has a fixed impedance of 50 Ohms. Unlike the impedance of the RF generator and the RF cable, the impedance of the plasma, which is driven by the RF power, varies. In order to effectively transmit RF power from the RF generator and the RF cable to the processing chamber, the impedance of the processing chamber is transformed to non-reactive 50 Ohms. Doing so maximizes the amount of RF power transmitted into the processing chamber. However, sometimes, the RF matching network interacting with the plasma impedance and source impedance will give rise to problems with plasma ignition, mismatch between the impedances, and instabilities in the plasma. As such, it is difficult to process the substrate using the RF generator when the RF matching network is used.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Embodiments of the disclosure provide systems, apparatus, methods and computer programs for controlling fast actuators in an impedance matching unit. It should be appreciated that the present embodiments can be implemented in numerous ways, e.g., a process, an apparatus, a system, a device, or a method on a computer readable medium. Several embodiments are described below.

In an embodiment, an impedance matching unit is described. The impedance matching unit includes an input port coupled to a radio frequency (RF) generator. The impedance matching unit further includes an output port coupled to a plasma chamber. The match includes a connection point located between the input port and the output port, a first reactive element coupled between the input port and the connection point, and a first switch coupled in parallel to the first reactive element. The impedance matching unit includes a second reactive element coupled between the connection point and the output port, and includes a second switch coupled in parallel to the second reactive element.

In one embodiment, an impedance matching unit is described. The impedance matching unit includes an input port coupled to an RF generator, an output port coupled to a plasma chamber, and a first connection point located between the input port and the output port. The impedance matching unit further includes a second connection point located between the input port and the output port, a first reactive element coupled to the first connection point, and a first switch coupled in series to the first reactive element. The first switch is coupled to a ground potential. The impedance matching unit includes a second reactive element coupled to the second connection point and a second switch coupled in series to the second reactive element. The second switch is coupled to the ground potential.

In one embodiment, a method is described. The method includes receiving a measurement of a parameter indicating stability of plasma within a plasma chamber. The measurement of the parameter is received from one or more sensors, such as a voltage sensor, or a current sensor, or a phase sensor, or an optical signal sensor, or an impedance sensor. The method further includes determining a plurality of positions of a plurality of switches in an impedance matching unit based on the measurement of the parameter. The impedance matching unit is located between an RF generator and a plasma chamber. Each of the plurality of switches is in parallel with a corresponding one of a plurality of reactive elements of the impedance matching unit. The method includes controlling the plurality of switches to be in the plurality of positions to achieve stability of the plasma.

Some advantages of the herein described systems and methods controlling fast actuators in the impedance matching unit include quickly changing a reactance of the impedance matching unit to synchronize an operation of the impedance matching unit with an operation of an RF generator. For example, when a state of an RF signal generated by the RF generator changes, the impedance matching unit is controlled via one or more switches to modify the reactance of the impedance matching unit in a fast manner. There is no need to mechanically control a variable reactor, such as a variable capacitor or a variable inductor, of the impedance matching unit by using a motor. The reactance of the impedance matching unit is modified to match an impedance of a load coupled to an output of the impedance matching unit with an impedance of a source coupled to an input of the impedance matching unit. As an example, the load is a combination of an RF transmission line and a plasma chamber and the source is a combination of the RF generator and an RF cable. By modifying the reactance of the impedance matching unit in the fast manner, plasma stability is achieved and a substrate placed within the plasma chamber is processed in a desirable manner.

Other advantages of the herein described systems and methods controlling fast actuators in the impedance matching unit include quickly changing the reactance of the impedance matching unit without controlling, via the motor, the variable reactor of the impedance matching unit. When the motor that is coupled to the capacitor or the inductor is controlled to modify a reactance of the impedance matching unit, an amount of time taken to modify the reactance is longer than when the switches are used. As such, by using the switches, the reactance of the impedance matching unit is modified quickly, e.g., in the fast manner, compared to when the motor is used to control the reactance. By modifying the reactance quickly, plasma stability is achieved with a fast change in the states of the RF signal and the semiconductor wafer is processed in the desirable manner.

Additional advantages of the herein described systems and methods include reducing, such as diminishing or reducing changes of an occurrence of, an instability in plasma before the instability occurs. By controlling the impedance matching unit using the fast actuators, before the instability occurs, chances of its occurrence are reduced. For example, when an RF generator changes a state of power level of an RF signal generated by the RF generator from a first state to a second state, an instability in the plasma can occur. By controlling the impedance matching unit using the fast actuators immediately after the change in the state of the RF signal, any chances of occurrence of the instability in the plasma are reduced.

Other aspects will become apparent from the following detailed description, taken in conjunction with the accompanying drawings.

### BRIEF DESCRIPTION OF THE DRAWINGS

The embodiments may best be understood by reference to the following description taken in conjunction with the accompanying drawings.

FIG. 1A is a diagram of an embodiment of a system to illustrate a control of actuators to control a series reactance of an impedance matching unit.

FIG. 1B is an embodiment of a table to illustrate a method for operating switches of the impedance matching unit of FIG. 1A.

FIG. 2A is a diagram of an embodiment of a system to illustrate a control of actuators to control a shunt reactance of an impedance matching unit.

FIG. 2B is an embodiment of a table to illustrate a method for operating switches of the impedance matching unit of FIG. 2A.

FIG. 3 is a diagram of an embodiment of a system to illustrate an impedance matching unit having a binary divider network.

FIG. 4 is a diagram of an embodiment of a plasma system to illustrate control of one or more reactive elements of an impedance matching unit based on feedback from one or more sensors.

FIG. 5 is a diagram of an embodiment of a plasma system to illustrate a control of reactances of the reactive elements of the impedance matching unit of FIG. 4 based on changes in a state of a variable of a radio frequency (RF) signal.

FIG. 6 is a diagram of an embodiment of a plasma system to illustrate a control of the impedance matching unit of FIG. 4 based on a state identified within a recipe of the RF signal.

FIG. 7A is a diagram of an embodiment of a table to illustrate correspondences between reactances of the impedance matching unit of FIG. 4, positions of the switches of the impedance matching unit, and states of the RF signal.

FIG. 7B is a diagram of an embodiment of a table to illustrate correspondences between reactances of the impedance matching unit of FIG. 4, positions of the switches of the impedance matching unit of FIG. 4, and the states of the RF signal.

### DETAILED DESCRIPTION

The following embodiments describe systems and methods for controlling fast actuators in an impedance matching unit. It will be apparent that the present embodiments may be practiced without some or all of these specific details. In other instances, well known operations have not been described in detail in order not to unnecessarily obscure the present embodiments.

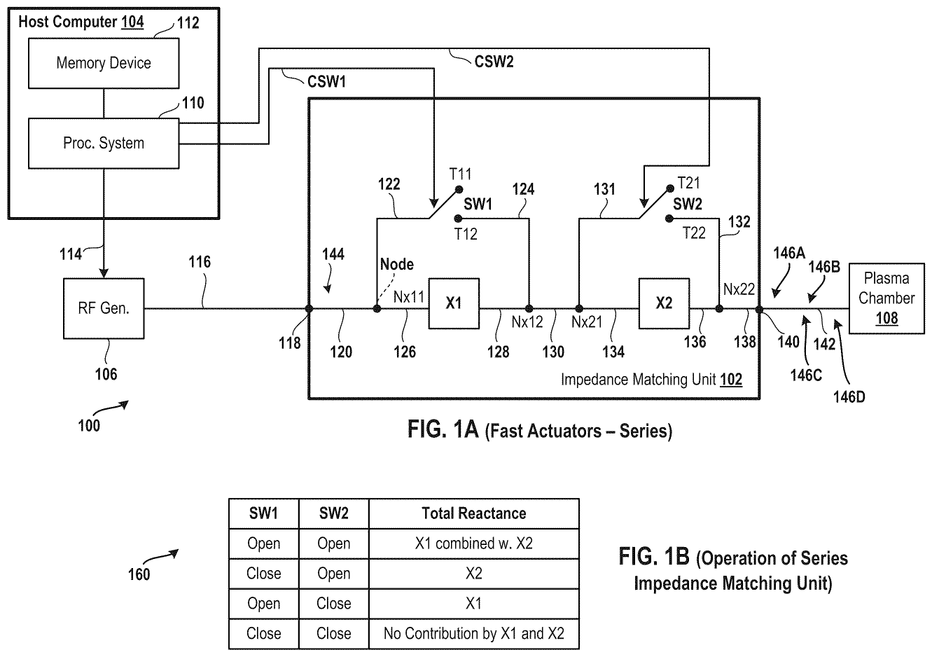

FIG. 1A is a diagram of an embodiment of a system 100 to illustrate a control of actuators, such as a switch SW1 and a switch SW2, to control a series reactance of an impedance matching unit 102. As an example, each switch, described herein, is a transistor or a group of transistors or a vacuum relay. An illustration of a transistor is a field effect transistor (FET), such as a radio frequency (RF) power FET. The system 100 includes a host computer 104, an RF generator 106, the impedance matching unit 102, and a plasma chamber 108. The host computer 104 includes a processor system 110 and a memory device 112. The impedance matching unit 102 includes a reactive element X1 and another reactive element X2.

Examples of the host computer 104 include a desktop computer, a laptop computer, a tablet, a controller, and a smart phone. As an example, the RF generator 106 is a 100 kilohertz (kHz) RF generator, or a 400 kHz RF generator, or a 2 megahertz (MHz) RF generator, or a 27 MHz RF generator, or a 60 MHz RF generator. Examples of the impedance matching unit 102 include an impedance matching network, an impedance matching circuit, a match, and an impedance match. To illustrate, the impedance matching unit 102 includes a network of reactive elements, such as series reactive elements or shunt reactive elements, or a combination thereof, that are coupled to each other. Examples of the plasma chamber 108 include a capacitively coupled plasma (CCP) chamber and an inductively coupled plasma (ICP) chamber.

As an example, the processor system 110 includes one or more processors. To illustrate, a processor, as used herein, is an application specific integrated circuit (ASIC), a central processing unit (CPU), a field programmable gate array (FPGA), a programmable logic device (PLD), an integrated controller, or a microcontroller. Examples of a memory device, as used herein, include a read-only memory (ROM) and a random access memory (RAM). To illustrate, the memory device 112 is a flash memory or a redundant array of independent discs (RAID).

Examples of a reactive element include an inductor and a capacitor. For example, the reactive element X1 is an inductor or a capacitor and the reactive element X2 is an inductor or a capacitor.

The processor system 110 is coupled to the memory device 112. Also, the processor system 110 is coupled via a transfer cable 114 to the RF generator 106. Examples of a transfer cable include a cable that allows a serial transfer of data, or a cable that allows a parallel transfer of data, and a cable that allows transfer of data using a Universal Serial Bus (USB) protocol.

The RF generator 106 is coupled via an RF cable 116, such as a coaxial cable, to an input port 118 of the impedance matching unit 102. An example of a port, as used herein, is a connector, which couples two or more conductors with each other. The input port 118 is coupled via an RF line 120 to a node NX11. An example of a node, as used herein, is a point at which two or more conductors are coupled, such as soldered, with each other. As used herein, a node or a port is sometimes referred to as a connection point. The node NX11 is coupled via an RF line 122 to a terminal T11 of the switch SW1. As an example, an RF line, as used herein, is one or more conductors. In the example, two or more of the conductors are coupled to each other. Also, another terminal T12 of the switch SW1 is coupled via an RF line 124 to a node NX12. Because the node NX11 is coupled to the switch SW1 and to the reactive element X1 and the node NX12 is coupled to the switch SW1 and to the reactive element X1, the reactive element X1 is coupled in parallel to the switch SW1. The reactive element X1 is coupled via an RF line 126 to the node NX11 and via an RF line 128 to the node NX12.

The node NX12 is coupled via an RF line 130 to a node NX21. The node NX21 is coupled via an RF line 131 to a terminal T21 of the switch SW2. Another terminal T22 of the switch SW2 is coupled via an RF line 132 to a node NX22. Because the node NX21 is coupled to the switch SW2 and to the reactive element X2 and the node NX22 is coupled to the switch SW2 and to the reactive element X2, the reactive element X2 is coupled in parallel to the switch SW2.

The node NX21 is coupled via an RF line 134 to the reactive element X2 and the reactive element X2 is coupled via an RF line 136 to the node NX22. The node NX22 is coupled via an RF line 138 to an output port 140 of the impedance matching unit 102. The output port 140 is coupled via an RF strap 142 to an electrode of the plasma chamber 108. As an example, the RF strap 142 is a flat strap fabricated from a metal, such as copper. To illustrate, the RF strap 142 is not an RF cable and does not have a 50 Ohm impedance. To further illustrate, an length of the RF strap 142 is less than a length of the RF cable 116. For example, the RF cable 116 has a length ranging from 4 feet to 30 feet and the RF strap 142 is less than a foot long. Examples of the electrode include a substrate support, an upper electrode, and a transformer coupled plasma (TCP) coil. To illustrate, when the plasma chamber 108 is the CCP chamber, the electrode coupled to the RF strap 142 is the substrate support or the upper electrode. In the illustration, when the RF strap 142 is coupled to the substrate support, the upper electrode of the CCP chamber is coupled to a ground potential or to an RF generator via an impedance matching unit. Further, in the illustration, when the RF strap 142 is coupled to the upper electrode, the substrate support is coupled to an RF generator via an impedance matching unit. As another illustration, when the plasma chamber 108 is the ICP chamber, the electrode coupled to the RF strap 142 is the substrate support or the TCP coil. In the illustration, when the electrode coupled to the RF strap 142 is the substrate support, the TCP coil is coupled to a ground potential or is coupled via an impedance matching unit to an RF generator. Moreover, in the illustration, when the electrode coupled to the RF strap 142 is the TCP coil, the substrate support is coupled via an impedance matching unit to an RF generator. Examples of the substrate support include an electrostatic chuck (ESC). Also, the processor system 110 is coupled to the switch SW1 via a switch connection CSW1 and is coupled to the switch SW2 via another switch connection CSW2. As an example, a switch connection is one or more conductors. In the example, two or more of the conductors are coupled to each other.

It should be noted that when a switch of an impedance matching unit, described herein, is a transistor or a group of transistors, the processor system 110 is coupled to the switch via an RF filter to protect the processor system 110. The RF filter filters out RF power that is reflected from the plasma chamber 108 via the impedance matching unit to the processor system 110 to protect the processor system 110. The RF filter is coupled between the processor system 110 and the switch. For example, one end of the RF filter is coupled to the processor system 110 and an opposite end of the RF filter is coupled to the switch.

Upon receiving a trigger signal from the processor system 110 via the transfer cable 114, the RF generator 106 generates an RF signal 144 and sends the RF signal 144 via the RF cable 116, the input port 118, and the RF line 120 to the node NX11. An example of the RF signal 144 is a continuous wave. Another example of the RF signal 144 is a multistate RF signal. The processor system 110 generates an OFF control signal and sends the OFF control signal via the switch connection CSW1 to the switch SW1. In response to receiving the OFF control signal, the terminal T11 is disconnected from the terminal T12 and the switch SW1 is open. Similarly, the processor system 110 generates an OFF control signal and sends the OFF control signal via the switch connection CSW2 to the switch SW2. In response to receiving the OFF control signal, the terminal T21 is disconnected from the terminal T22 and the switch SW2 is open. It should be noted that when a switch, described herein, is open, the switch is in an open position.

When the switches SW1 and SW2 are open, the RF signal 144 is transferred via the reactive elements X1 and X2 that are coupled to each other in series, and an impedance of the RF signal 144 is modified by the reactive elements X1 and X2 to output a modified RF signal 146A. For example, the reactive elements X1 and X2 match an impedance of a load coupled to the output port 140 with an impedance of a source coupled to the input port 118 to output the modified RF signal 146A based on the RF signal 144. An example of the load coupled to the output port 140 includes the RF strap 142 and the plasma chamber 108, and an example of the source coupled to the input port 118 includes the RF generator 106 and the RF cable 116. The modified RF signal 146A is sent from the node NX22 via the RF line 138, the output port 140, and the RF strap 142 and to the electrode of the plasma chamber 108.

When one or more process gases, such as oxygen containing gas, or a nitrogen containing gas, or a fluorine containing gas, or combination thereof, are supplied to the plasma chamber 108 in addition to the modified RF signal 146A, plasma is generated or maintained within the plasma chamber 108. A substrate, such as a semiconductor wafer, is placed on top of the substrate support within the plasma chamber 108 for processing by the plasma. Examples of processing the substrate include depositing a material on the substrate, etching the substrate, and cleaning the substrate.

As a first alternative to sending the OFF control signals to the switches SW1 and SW2, the processor system 110 generates an ON control signal and sends the ON control signal via the switch connection CSW1 to the switch SW1. In response to receiving the ON control signal, the terminal T11 is connected to the terminal T12 and the switch SW1 is closed. The processor system 110 generates and sends the OFF control signal via the switch connection CSW2 to open the switch SW2. It should be noted that when a switch, described herein, is closed, the switch is in a closed position.

When the switch SW1 is closed and the switch SW2 is open, the reactive element X1 acts as a short circuit and the RF signal 144 is transferred via the short circuit, the node NX12, and the RF line 130 to the reactive element X2. An impedance of the RF signal 144 is modified by the reactive element X2, without being modified by the reactive element X1, to output a modified RF signal 146B. For example, the reactive element X2 matches the impedance of the load coupled to the output port 140 with the impedance of a source coupled to the node NX21 to output the modified RF signal 146B at the node NX22 based on the RF signal 144. An example of the source coupled to the node NX21 includes the short circuit, the RF cable 116, and the RF generator 106. The modified RF signal 146B is sent from the node NX22 via the RF line 138, the output port 140, and the RF strap 142 and to the electrode of the plasma chamber 108. When the one or more process gases are supplied to the plasma chamber 108 in addition to the modified RF signal 146B, the plasma is generated or maintained within the plasma chamber 108 for processing the substrate.

As a second alternative to sending the OFF control signals to the switches SW1 and SW2, the processor system 110 generates an ON control signal and sends the ON control signal via the switch connection CSW2 to the switch SW2. In response to receiving the ON control signal, the terminal T21 is connected to the terminal T22 and the switch SW2 is closed. The processor system 110 generates and sends the OFF control signal via the switch connection CSW1 to open the switch SW1.

When the switch SW2 is closed and the switch SW1 is open, the reactive element X2 acts as a short circuit and the RF signal 144 is transferred via the reactive element X1 to the short circuit. An impedance of the RF signal 144 is modified by the reactive element X1, without being modified by the reactive element X2, to output a modified RF signal 146C. For example, the reactive element X1 matches the impedance of the load coupled to the node NX12 with the impedance of the source coupled to the input port 118 to output the modified RF signal 146C at the node NX12 based on the RF signal 144. An example of the load coupled to the node NX12 includes the short circuit, the RF strap 142, and the plasma chamber 108. The modified RF signal 146C is sent from the node NX12 via the RF line 130, the short circuit, the RF line 138, the output port 140, and the RF strap 142 to the electrode of the plasma chamber 108. When the one or more process gases are supplied to the plasma chamber 108 in addition to the modified RF signal 146C, the plasma is generated or maintained within the plasma chamber 108 for processing the substrate.

As a third alternative to sending the OFF control signals to the switches SW1 and SW2, the processor system 110 generates the ON control signal and sends the ON control signal via the switch connection CSW1 to the switch SW1. Also, the processor system 110 generates the ON control signal and sends the ON control signal via the switch connection CSW2 to the switch SW2. In response to receiving the ON control signals, both the switches SW1 and SW2 are closed.

When the switches SW1 and SW2 are closed, the reactive elements X1 and X2 act as the short circuits and the RF signal 144 is transferred via the input port 118 to the short circuits of the impedance matching unit 102. An impedance of the RF signal 144 is insubstantially modified, such as not modified or modified below a predetermined threshold, to output a modified RF signal 146D at the output port 140. For example, the short circuits match the impedance of the load coupled to the output port 140 with the impedance of the source coupled to the input port 118 to output the modified RF signal 146D. To illustrate, the modified RF signal 146D is the same as the RF signal 144. To further illustrate, the RF signal 144 is transferred via the RF line 120, the node NX11, a first one of the short circuits, the node NX12, the RF line 130, a second one of the short circuits, the node NX22, and the RF line 138 to the output port 140. The modified RF signal 146D is sent from the output port 140 via the RF strap 142 to the electrode of the plasma chamber 108. When the one or more process gases are supplied to the plasma chamber 108 in addition to the modified RF signal 146D, the plasma is generated or maintained within the plasma chamber 108 for processing the substrate.

In one embodiment, the RF line 130 is replaced with a reactive element. For example, a series reactive element or a shunt reactive element is placed at a location of the RF line 130 to be coupled between the nodes NX12 and NX21.

In an embodiment, instead of the RF strap 142, a series of RF straps coupled to each other is used.

FIG. 1B is an embodiment of a table 160 to illustrate a method for operating the switches SW1 and SW2. When both the switches SW1 and SW2 are open, a combined reactance of the reactive elements X1 and X2 is applied to the RF signal 144 to modify the impedance of the RF signal 144 to output the modified RF signal 146A (FIG. 1A). An example of a reactance is a capacitive reactance or an inductive reactance. When the switch SW1 is closed and the switch SW2 is open, a reactance of the reactive element X2 is applied to the RF signal 144 without applying the reactance of the reactive element X1 to modify the impedance of the RF signal 144 to output the modified RF signal 146B (FIG. 1A). Also, when the switch SW2 is closed and the switch SW1 is open, a reactance of the reactive element X1 is applied to the RF signal 144 without applying the reactance of the reactive element X2 to modify the impedance of the RF signal 144 to output the modified RF signal 146C. When the switch SW1 is closed and the switch SW2 is closed, reactances of the reactive elements X1 and X2 are not applied to the RF signal 144 to insubstantially modify the impedance of the RF signal 144 to output the modified RF signal 146D.

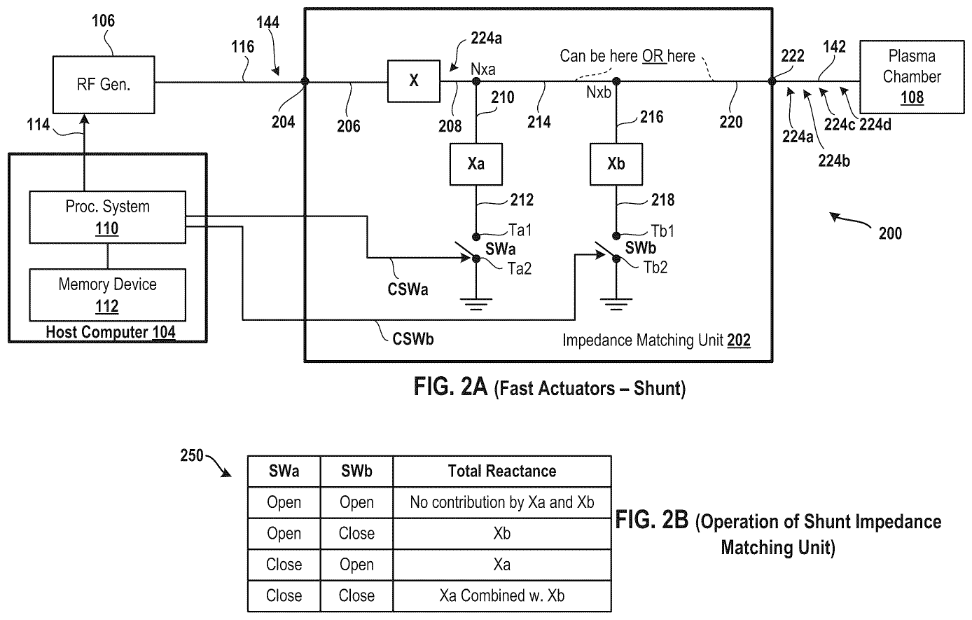

FIG. 2A is a diagram of an embodiment of a system 200 to illustrate a control of actuators, such as a switch SWa and a switch SWb, to control a shunt reactance of an impedance matching unit 202. The system 200 includes the host computer 104, the RF generator 106, the impedance matching unit 202, and the plasma chamber 108. The impedance matching unit 102 includes a reactive element Xa, another reactive element Xb, and yet another reactive element X. As an example, the reactive element Xa is an inductor or a capacitor, the reactive element Xb is an inductor or a capacitor, and the reactive element X is a capacitor or an inductor.

The RF generator 106 is coupled via the RF cable 116 to an input port 204 of the impedance matching unit 202. The input port 204 is coupled via an RF line 206 to the reactive element X. The reactive element X is coupled via an RF line 208 to a node Nxa. The node Nxa is coupled via an RF line 210 to the reactive element Xa. The reactive element Xa is coupled via an RF line 212 to a terminal Ta1 of the switch SWa to be coupled in series with the switch SWa. An opposite terminal Ta2 of the switch SWa is coupled to the ground potential. Also, the node Nxa is coupled via an RF line 214 to the node Nxb. The node Nxb is coupled via an RF line 216 to the reactive element Xb. The reactive element Xb is coupled via an RF line 218 to a terminal Tb1 of the switch SWb to be coupled in series with the switch SWb. An opposite terminal Tb2 of the switch SWb is coupled to the ground potential. The node Nxb is coupled via an RF line 220 to an output port 222 of the impedance matching unit 202. The output port 222 is coupled via the RF strap 142 to the electrode of the plasma chamber 108. Also, the processor system 110 is coupled to the switch SWa via a switch connection CSWa and is coupled to the switch SWb via another switch connection CSWb.

The RF signal 144 is sent from the RF generator 106 via the RF cable 116, the input port 204, and the RF line 206 to the reactive element X. The reactive element X modifies an impedance of the RF signal 144 to output a modified RF signal 224a, which is transferred to the node Nxa.

The processor system 110 generates an OFF control signal and sends the OFF control signal via the switch connection CSWa to the switch SWa. In response to receiving the OFF control signal, the terminal Ta2 is disconnected from the terminal Tal and the switch SWa is open. Similarly, the processor system 110 generates an OFF control signal and sends the OFF control signal via the switch connection CSWb to the switch SWb2. In response to receiving the OFF control signal, and the terminal Tb2 is disconnected from the terminal Tb1, and the switch SWb is open. When the switches SWa and SWb are open, both the reactive elements Xa and Xb act as open circuits and the modified RF signal 224a is transferred from the node Nxa via the RF line 214, the node NXb, the RF line 220, the output port 222, and the RF strap 142 to the electrode of the plasma chamber 108. When the one or more process gases are supplied to the plasma chamber 108 in addition to the modified RF signal 224a, plasma is generated or maintained within the plasma chamber 108.

As a first alternative to sending the OFF control signals to the switches SWa and SWb, the processor system 110 generates an ON control signal and sends the ON control signal via the switch connection CSWa to the switch SWa. In response to receiving the ON control signal, the terminal Ta2 is connected to the terminal Tal and the switch SWa is closed. The processor system 110 generates and sends the OFF control signal via the switch connection CSWb to open the switch SWb.

When the switch SWa is closed and the switch SWb is open, the reactive element Xb acts as an open circuit, the reactive element Xa acts as a shunt circuit, and the modified RF signal 224a is transferred via the RF line 208 to the node Nxa. The reactive element Xa modifies an impedance of the modified RF signal 224a to output a modified RF signal 224b at the node Nxa. The reactive element Xb does not modify an impedance of the modified RF signal 224b. The modified RF signal 224b is transferred from the node Nxa via the RF line 214, the node Nxb, the RF connection line 220, and the RF strap 142 to the electrode of the plasma chamber 108. When the one or more process gases are supplied to the plasma chamber 108 in addition to the modified RF signal 224b, the plasma is generated or maintained within the plasma chamber 108 for processing the substrate.

As a second alternative to sending the OFF control signals to the switches SWa and SWb, the processor system 110 generates the OFF control signal and sends the OFF control signal via the switch connection CSWa to the switch SWa to open the switch SWa. Also, the processor system 110 the ON control signal and sends the ON control signal via the switch connection CSWb to the switch SWb to close the switch SWb. In response to receiving the ON control signal, the terminal Tb2 is connected to the terminal Tb1 and the switch SWb is closed.

When the switch SWa is open and the switch SWb is closed, the reactive element Xa acts as an open circuit, the reactive element Xb acts as a shunt circuit, and the modified RF signal 224a is transferred via the RF line 208, the node Nxa, and the RF line 214 to the node Nxb. The reactive element Xa does not modify an impedance of the modified RF signal 224a. The reactive element Xb modifies the impedance of the modified RF signal 224a at the node Nxb to output a modified RF signal 224c at the node Nxb. The modified RF signal 222c is transferred from the node Nxb via the RF line 220, the output port 222, and the RF strap 142 to the electrode of the plasma chamber 108. When the one or more process gases are supplied to the plasma chamber 108 in addition to the modified RF signal 224c, the plasma is generated or maintained within the plasma chamber 108 for processing the substrate.

As a third alternative to sending the OFF control signals to the switches SWa and SWb, the processor system 110 generates the ON control signal and sends the ON control signal via the switch connection CSWa to the switch SWa. Also, the processor system 110 generates the ON control signal and sends the ON control signal via the switch connection CSWb to the switch SWb. In response to receiving the ON control signals, both the switches SWa and SWb are closed.

When the switches SWa and SWb are closed, the reactive elements Xa1 and Xb act as the shunt circuits, and the RF signal 224a is sent from the reactive element X via the RF line 208 to the node Nxa to output the modified RF signal 224b at the node Nxa. Also, the modified RF signal 224b is send via the RF line 214 to the node Nxb. The reactive element Xb modifies an impedance of the modified RF signal 224b at the node Nxb to output a modified RF signal 224d at the node Nxb. The modified RF signal 224d is transferred from the node Nxb via the RF line 220, the output port 222, and the RF strap 142 to the electrode of the plasma chamber 108. When the one or more process gases are supplied to the plasma chamber 108 in addition to the modified RF signal 222d, the plasma is generated or maintained within the plasma chamber 108 for processing the substrate.

In one embodiment, the reactive element X is coupled between the nodes Nxa and Nxb or between the node Nxb and the output port 222 instead of being coupled between the input port 204 and the node Nxa.

FIG. 2B is an embodiment of a table 160 to illustrate a method for operating the switches SWa and SWb. When the switch SWa is open and the switch SWa is open, reactances of the reactive elements Xa and Xb are not applied to the modified RF signal 224a to insubstantially modify the impedance of the modified RF signal 224a to output the modified RF signal 224a at the output port 222. When the switch SWa is closed and the switch SWb is open, a reactance of the reactive element Xa is applied to the modified RF signal 224a without applying the reactance of the reactive element Xb to output the modified RF signal 224b (FIG. 1A). Also, when the switch SWb is closed and the switch SWa is open, a reactance of the reactive element Xb is applied to the RF signal 224a without applying the reactance of the reactive element Xa to modify the impedance of the RF signal 224a to output the modified RF signal 224c. When both the switches SWa and SWb are closed, a combined reactance of the reactive elements Xa and Xb is applied to the modified RF signal 224a to modify the impedance of the modified RF signal 224a to output the modified RF signal 224d.

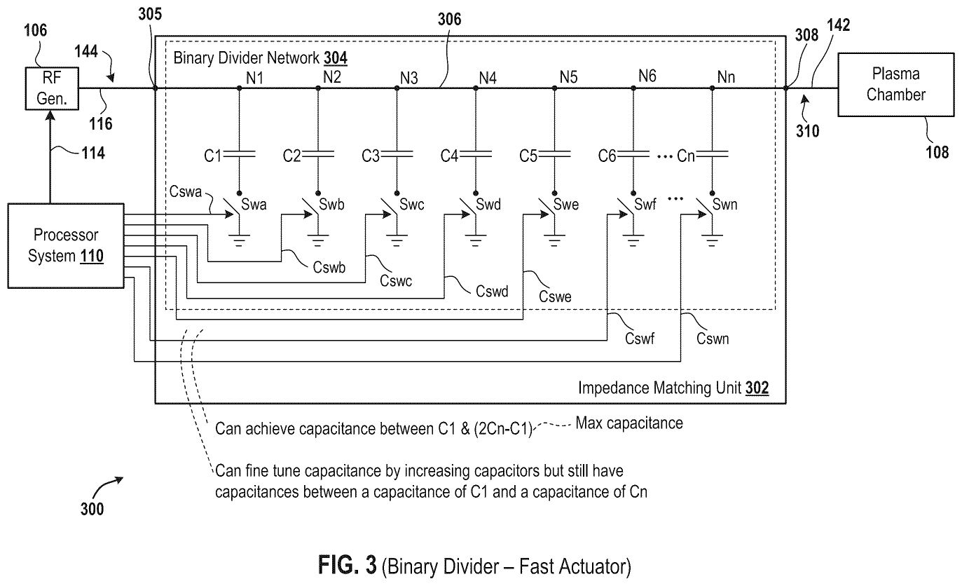

FIG. 3 is a diagram of an embodiment of a system 300 to illustrate an impedance matching unit 302 having a binary divider network 304. The system 300 includes the processor system 110, the RF generator 106, the impedance matching unit 302, and the plasma chamber 108.

The binary divider network 304 includes switches SWa, SWb, SWc, SWd, SWe, SWf, until a switch SWn, and capacitors C1, C2, C3, C4, C5, C6, until a capacitor Cn, where n is a positive integer. As an example, each successive capacitor C1 through Cn has a capacitance that is double a capacitance of a preceding capacitor. To illustrate, the capacitor C1 has a capacitance of 8 picoFarads (pF), the capacitor C2 is a capacitance of 16 pF, the capacitor C3 has a capacitance of 32 pF, the capacitor C4 has a capacitance of 64 pF the capacitor C5 is a capacitance of 128 pF, the capacitor C6 is a capacitance of 256 pF, and the capacitor Cn has a capacitance of 512 pF. Each of C1 through Cn also represents a capacitance of the respective capacitor. For example, Cn is a capacitance of the capacitor Cn.

The RF generator 106 is coupled via the RF cable 116 to an input port 305 of the impedance matching unit 302. The input port 305 is coupled via an RF line 306 to an output port 308 of the impedance matching unit 302. The output port 308 is coupled via the RF strap 142 to the electrode of the plasma chamber 108.

The capacitors C1 through Cn are coupled to the RF line 306 to form shunt circuits. For example, the capacitor C1 is coupled to a node N1 on the RF line 306, the capacitor C2 is coupled to a node N2 on the RF line 306, the capacitor C3 is coupled to a node N3 on the RF line 306, the capacitor C4 is coupled to a node N4 on the RF line 306, the capacitor C5 is coupled to a node N5 on the RF line 306, the capacitor C6 is coupled to a node N6 on the RF line 306, and the capacitor Cn is coupled to a node Nn on the RF line 305. Also, each capacitor C1 through Cn is coupled to a respective terminal of the switches SW1 through SWn. For example, the capacitor C1 is coupled to a first terminal of the switch SW1 and the capacitor Cn is coupled to a first terminal of the switch Sn. Second terminals of the switches SW1 through SWn are coupled to the ground potential.

The input port 305 is coupled via the nodes N1 through Nn to the output port 308. Also, the processor system 110 is coupled via a respective switch connection to the switches SW1 through SWn. For example, the processor system 110 is coupled via the switch connection CSWa to the switch SWa, the switch connection CSWb to the switch SWb, a switch connection CSWc to the switch SWc, a switch connection CSWd to the switch SWd, a switch connection CSWe to the switch SWe, a switch connection CSWf to the switch SWf, and a switch connection CSWn connection to the switch SWn.

The processor system 110 controls one or more of the switches SW1 through SWn to open or close via respective one or more of the switch connections CSWa through CSWn in the same manner in which the processor system 110 controls one or more of the switches SWa and SWb (FIG. 2A). When the one or more of the switches SW1 through SWn are closed, respective one or more capacitances of one or more of the capacitors C1 through Cn that are coupled to the closed switches modify an impedance of the RF signal 144 to output a modified RF signal 310 at the output port 308. The one or more of the capacitors C1 through Cn that are coupled to the closed switches act as shunt capacitors. Moreover, the remaining of the capacitors C1 through Cn that are coupled to the remaining of the switches SW1 through SWn that are open do not modify the impedance of the RF signal 144. By controlling the switches SW1 through SWn, a capacitance between the capacitance C1 and a capacitance (2Cn−C1) is applied to modify the impedance of the RF signal 144 to output the modified RF signal 310.

The modified RF signal 310 is sent from the output port 308 via the RF strap 142 to the electrode of the plasma chamber 108. When the one or more process gases are supplied to the plasma chamber 108 in addition to the modified RF signal 310, the plasma is generated or maintained within the plasma chamber 108 for processing the substrate. It should be noted that by modifying a number of the capacitors C1 through Cn used as shunt circuits, a combined capacitance that is applied by the capacitors C1 through Cn is fine tuned.

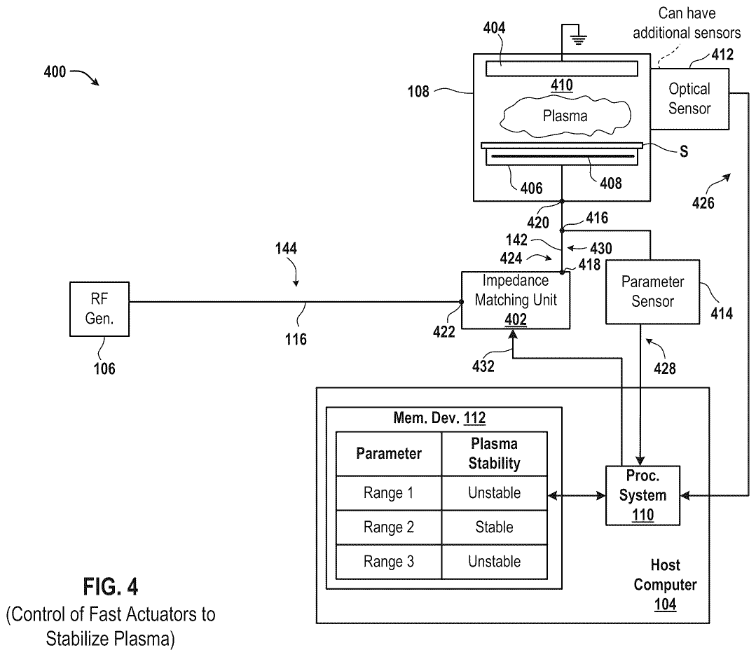

FIG. 4 is a diagram of an embodiment of a plasma system 400 to illustrate control of one or more reactive elements of an impedance matching unit 402 based on feedback from one or more sensors. The plasma system 400 includes the RF generator 106, the impedance matching unit 402, and the plasma chamber 108. The plasma system 400 further includes the host computer 104.

The plasma chamber 108 includes an upper electrode 404 and a substrate support 406. An example of the substrate support includes an electrostatic chuck (ESC). The substrate support 406 includes a lower electrode 408 embedded within it. Each of the upper electrode 404 and the lower electrode 408 is fabricated from a metal, such as aluminum or an alloy of aluminum. A substrate S, such as a semiconductor wafer, is based on a top surface of the substrate support 406 for processing. Between the upper electrode 404 and the substrate support 406 there is a gap 410.

Examples of the impedance matching unit 402 include the impedance matching unit 102 (FIG. 1A), the impedance matching unit 202 (FIG. 2A), and the impedance matching unit 302 (FIG. 3). To illustrate, the impedance matching unit 402 is the impedance matching unit 102 or 202 or 302. The sensors of the plasma system 400 include an optical sensor 412 and a parameter sensor 414. Examples of the parameter sensor 414 include a complex voltage and current (VI) sensor, a voltage (V) sensor, and a current (I) sensor. An example of the optical sensor 412 includes a spectrometer. To illustrate, the optical sensor 412 senses light emitted from plasma generated within the gap 410 to output electrical signals based on wavelengths of the light. The optical sensor 412 has a view directed towards the gap 410.

The parameter sensor 414 is coupled to a point 416 on the RF strap 142. The point 416 lies between an output 418 of the impedance matching unit 402 and an input 420 of the plasma chamber 108. Examples of the output 418 include the output port 140 (FIG. 1A), the output port 222 (FIG. 2A), and the output port 308 (FIG. 3).

The processor system 110 is coupled to the impedance matching unit 402 via switch connections 432. Examples of the switch connections 432 include the switch connections CSW1 and CSW2 (FIG. 1A), or the switch connections CSWa and CSWb (FIG. 2A), or the switch connections CSWa through CSWn (FIG. 3).

The impedance matching unit 402 receives the RF signal 144 at its input 422 and matches an impedance of a load coupled to the output 418 with an impedance of a source coupled to the input 422 to output a modified RF signal 424 at the output 418. Examples of the input 422 include the input port 118 (FIG. 1A), the input port 204 (FIG. 2A), and the input port 305 (FIG. 3). An example of the load coupled to the output 418 includes the RF strap 142 and the plasma chamber 108. An example of the source coupled to the input 422 includes the RF cable 116 and the RF generator 106.

When the one or more process gases are supplied to the gap 410 in addition to the modified RF signal 424, and the plasma is generated within the gap 410 for processing the substrate S, the optical sensor 412 measures a parameter, such as one or more wavelengths, of light that is output from the plasma to generate a measurement signal 426, and sends the measurement signal 426 to the processor system 110. The measurement signal 426 includes one or more measured values of the parameter. Moreover, the parameter sensor 414 measures a parameter, such as a complex voltage and current, a complex voltage, or a complex current, to output a measurement signal 428 and sensor measurement signal 428 to the processor system 110. The measurement signal 428 includes one or more measured values of the parameter.

The processor system 110 receives the measurement signals 426 and 428, and determines based on one or more of the measurement signals 426 and 428 whether the plasma is stable. For example, the processor system 110 compares the measured values of the parameter received within the measurement signal 426 or 428 with a predetermined parameter range, such as a range 2, to determine whether the measured values lie within the predetermined parameter range. In the example, upon determining that the measured values do not lie within the predetermined parameter range and instead lie within a range 1 or a range 3, the processor system 110 determines that the plasma is unstable and controls, such as opens or closes, one or more of the switches of the impedance matching unit 402 to apply one or more reactances of one or more reactive elements of the impedance matching unit 402 to further modify an impedance of the RF signal 144 to output a modified RF signal 430. Further, in the example, the processor system 110 continues to control one or more of the reactive elements of the impedance matching unit 402 until it is determined from the measured values of the parameter that the measured values are located within the predetermined parameter range. Also, in the example, upon determining that the measured values lie within the predetermined parameter range, the processor system 110 determines that the plasma is stable or has stability and does not further control the reactive elements of the impedance matching unit 402. When the measured values lie with the predetermined parameter range, the modified RF signal 430 is provided at the output 418 by the impedance matching unit 402. When the one or more process gases are supplied to the gap 410 with the modified RF signal 430, the substrate S is processed by the plasma within the gap 410. Further, in the example, the plasma is unstable or has instability when the measured values lie outside the predetermined parameter range, such as lie within the range 1 or the range 3. It should be noted that in the example, the ranges 1 and 3 correspond to the plasma being unstable and the range 2 corresponds to the plasma being stable. An illustration of the plasma being stable is a uniformity in an impedance of plasma across a top surface of the substrate S to achieve a uniformity in a processing rate, such as an etch rate or a deposition rate, across the top surface. An illustration of the plasma being unstable is a lack of the uniformity.

It should be noted that when the plasma is unstable, it is outside a predetermined range of stability. Also, when the plasma is stable, it is within the predetermined range of stability.

Examples of the reactive elements of the impedance matching unit 402 include the reactive elements X1 and X2 (FIG. 1A), or the reactive elements Xa and Xb (FIG. 2A), or the capacitors C1 through Cn (FIG. 3). Also examples of the switches of the impedance matching unit 402 include the switches SW1 and SW2 (FIG. 1A), or the switches SWa and SWb (FIG. 2A), or the switches SWa through SWn (FIG. 3). Examples of the modified RF signal 430 include the modified RF signal 146A, or 146B, or 146C, or 146D (FIG. 1A), or 224a, or 224b, or 224c, or 224d (FIG. 2A), or 310 (FIG. 3).

In one embodiment, the plasma system 400 includes one or more additional sensors, such as a VI sensor or a V sensor or an I sensor, and the processor system 110 controls the impedance matching unit 402 based on one or more measured signals received from the one or more additional sensors instead or of in addition to controlling the impedance matching unit 402 based on one or more of the measurement signals 426 and 428. For example, the one or more additional sensors are coupled to the RF cable 116 and to the processor system 110.

In an embodiment, the parameter sensor 414 is coupled to the output 418 or to the input 420.

In one embodiment, the plasma system 400 excludes the parameter sensor 414 or the optical sensor 412.

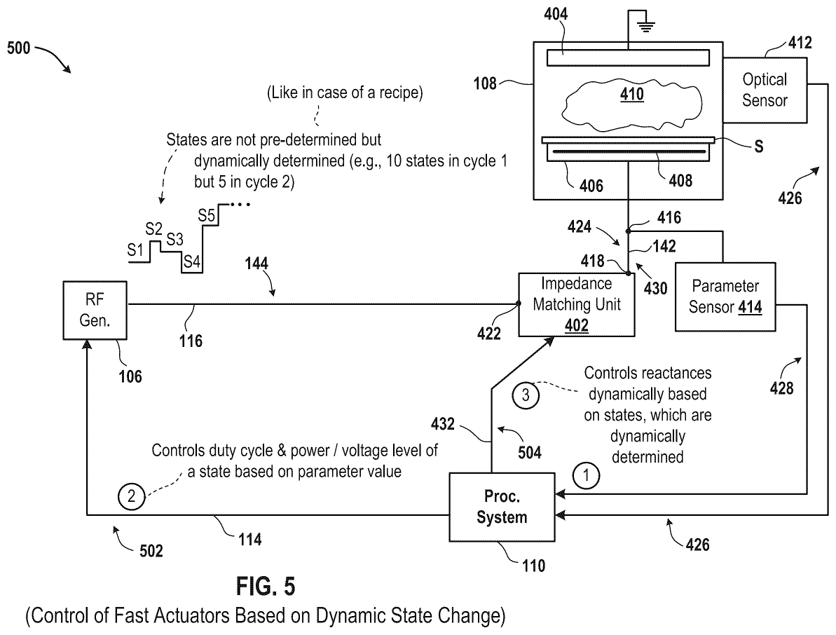

FIG. 5 is a diagram of an embodiment of a plasma system 500 to illustrate a control of reactances of the reactive elements of the impedance matching unit 402 based on changes in a state of a variable, such as a power or frequency or voltage, of the RF signal 144. An example of the state of the variable is a variable level, such as a power level or a frequency level or a voltage level. The variable level includes a statistical value, such as a mean or a median, of multiple values of the variable. For example, a first variable level has a first statistical value and a second variable level has a second statistical value. The first statistical value is different from, such is greater than or lower than, the second statistical value. For example, a minimum of a first plurality of values based on which the first statistical value is greater than a maximum of a second plurality of values based on which the second statistical value is generated. In the example, the first statistical value is greater than the second statistical value.

The plasma system 500 is the same as the plasma system 400 except that in the plasma system 500, the processor system 110 controls the impedance matching unit 402 dynamically based on the changes in the state of the variable. The processor system 110 receives the measurement signals 426 and 428, and determines based on one or more of the measurement signals 426 and 428, whether to modify the state of the variable, or whether to modify the reactance of the impedance matching unit 402, or a combination thereof. For example, during a time period in which a state Sm of the variable of the RF signal 144 is output from the RF generator 106, the processor system 110 determines that the measured values of the parameter received within the measurement signal 426 or 428 is not within the predetermined parameter range, such as not within the range 2 (FIG. 4), where m is at least zero. In the example, upon determining that the measured values of the parameter received within the measurement signal 426 or 428 are not within the predetermined parameter range, the processor system 110 determines to modify the state Sm of the RF signal 144 to another state S(m+p), where p is a positive integer. Further, in the example, upon determining to modify the state Sm, the processor system 110 sends a state modification signal 502 via the transfer cable 114 to the RF generator 106. Upon receiving the state modification signal 502, the RF generator 106 changes the state Sm of the RF signal 144 to the state S(mp). Moreover, within a predetermined time period from which the state modification signal 502 is sent or at the same time at which the state modification signal 502 is sent, in the example, the processor system 110 receives the measured values within the measurement signal 426 or 428, determines that the measured values of the parameter received within the measurement signal 426 or 428 are not within the predetermined parameter range, and sends one or more control signals 504, such as one or more ON control signals or one or more OFF control signals or a combination thereof, via respective one or more of the switch connections 432 to the impedance matching unit 402.

In the example, the one or more control signals 504 are sent to control respective one or more of the switches of the impedance matching unit 402 to modify the reactance of the impedance matching unit 402. To illustrate, the processor system 110 sends the ON control signal to the switch SW1 to close the switch SW1 and the OFF control signal to the switch SW2 to open the switch SW2 (FIG. 1A). As another illustration, the processor system 110 sends the ON control signal to the switch SWa to close the switch SWa and sends the ON control signal to the switch SWb to close the switch SWb (FIG. 2A). As yet another illustration, the processor system 110 sends the ON control signals to the switches SWa through SWd to close the switches SWa through SWd and sends the OFF control signals to the switches SWe through SWn to open the switches SWe through SWn (FIG. 3). In the example, the processor system 110 continues to modify the state of the RF signal 144 or the reactance of the impedance matching unit 402 or a combination thereof until the measured values of the parameter are within the predetermined parameter range. Further in the example, upon determining that the measured values of the parameter are within the predetermined parameter range, the processor system 110 maintains the state of the RF signal 144 and the reactance of the impedance matching unit 402 for which the measured values of the parameter are within the predetermined parameter range.

When the state Sm of the RF signal 144 is modified or the reactance of the impedance matching unit 402 is modified until the measured values of the parameter are within the predetermined parameter range, an impedance of the RF signal 144 is modified to output the modified RF signal 430 at the output 418. By modifying the states of the RF generator 106 dynamically based on the measured values of the parameter of the measurement signal 426 or 428, the RF generator 106 generates the RF signal 144 having a different number of states during each cycle of a clock signal. For example, the RF signal 144 has four states during a first cycle of the clock signal and five states during a second cycle of the clock signal. As another example, the RF signal 144 has three states during the first cycle and seven states during the second cycle. The clock signal is generated by the processor system 110 and sent to the RF generator 106 via the transfer cable 114.

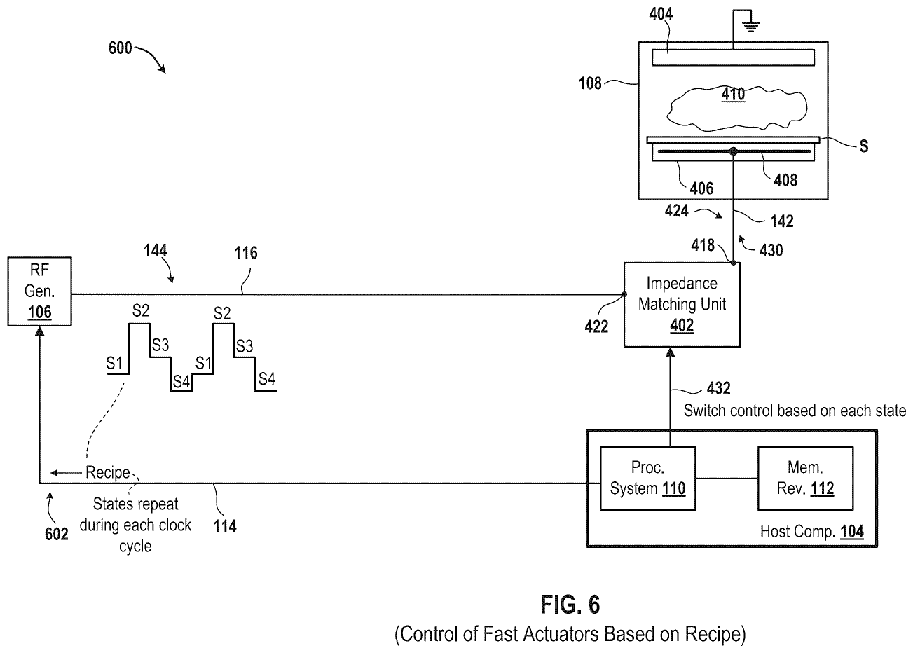

FIG. 6 is a diagram of an embodiment of a plasma system 600 to illustrate a control of the impedance matching unit 402 based on a state identified within a recipe of the RF signal 144. The plasma system 600 is the same as the plasma system 500 (FIG. 5) except the plasma system 600 excludes the parameter sensor 414 and the optical sensor 412 (FIG. 5). The processor system 110 generates a recipe signal 602 and sends the recipe signal 602 via the transfer cable 114 to the RF generator 106. The recipe signal 602 includes multiple states of the variable of the RF signal 144, and includes an instruction that the same multiple states are to repeat during each cycle of the clock signal. For example, the recipe signal 602 includes multiple power levels of the RF signal 144. Upon receiving the recipe signal 602, the RF generator 106 generates the RF signal 144 having the multiple states during each cycle of the clock signal.

For each state of the RF signal 144 that is output from the RF generator 106, the processor system 110 controls the impedance matching unit 402 to achieve a reactance for the state to output the modified RF signal 430. For example, during a time period in which the RF signal 144 has the state Sm, the processor system 110 controls the impedance matching unit 402 to achieve a first reactance that corresponds to the state Sm and during a time period in which the RF signal 144 has another state S(m+p), the processor system 110 controls the impedance matching unit 402 to achieve a second reactance that corresponds to the state S(m+p). In the example, the first reactance is different from, such as greater than or less than, the second reactance. Further in the example, the switches of the impedance matching unit 402 are controlled by the processor system 110 in a different manner to achieve each of the different reactances. To illustrate, to achieve the first reactance, the processor system 110 sends a first set of control signals to the switches SW1 and SW2 of the impedance matching unit 410 to open the switch SW1 and close the switch SW2. Further in the illustration, the processor system 110 sends a second set of control signals to the switches SW1 and SW2 of the impedance matching unit 410 to close the switch SW1 and open the switch SW2 to achieve the second reactance. Also, in the example, the correspondences, such as one-to-one or unique relationships, between the states of the RF signal 144, the reactances of the impedance matching unit 402, and positions of the switches to achieve the reactance are stored in the memory device 112 of the host computer 104 for access by the processor system 110. Illustrations of the positions of the switches include the open and closed positions.

As another example, during a first time period in which the RF generator 106 is controlled to transition the RF signal 144 to the state Sm from a preceding state S(m−1), the processor system 110 controls the impedance matching unit 402 to modify a first reactance that corresponds to the state S(m−1) to a second reactance that corresponds to the state Sm. In the example, both the state Sm and the second reactance are achieved simultaneously by controlling the RF generator 106 and the impedance matching unit 402 dynamically, in real-time, during the first time period. Further, in the example, during a second time period in which the RF generator 106 is controlled to transition the RF signal 144 to a state S(m+1) from the state Sm, the processor system 110 controls the impedance matching unit 402 to modify the second reactance that corresponds to the state Sm to a third reactance that corresponds to the state S(m+1). In the example, both the state S(m+1) and the third reactance are achieved simultaneously by controlling the RF generator 106 and the impedance matching unit 402 dynamically, in real-time, during the second time period.

As yet another example, at a first time at which the RF generator 106 is controlled to transition the RF signal 144 to the state Sm from a preceding state S(m−1), the processor system 110 controls the impedance matching unit 402 to modify a first reactance that corresponds to the state S(m−1) to a second reactance that corresponds to the state Sm. In the example, both the state Sm and the second reactance are achieved simultaneously by controlling the RF generator 106 and the impedance matching unit 402 dynamically, in real-time, at the first time. Further, in the example, at a second time at which the RF generator 106 is controlled to transition the RF signal 144 to the state S(m+1) from the state Sm, the processor system 110 controls the impedance matching unit 402 to modify the second reactance that corresponds to the state Sm to the third reactance that corresponds to the state S(m+1). In the example, both the state S(m+1) and the third reactance are achieved simultaneously by controlling the RF generator 106 and the impedance matching unit 402 dynamically, in real-time, at the second time.

By controlling reactance of the impedance matching unit 402 dynamically, in real time, with a change in a state of the RF signal 144, chances of an occurrence of instability in the plasma are reduced. For example, before a parameter sensor, such as the parameter sensor 414 (FIG. 5), if used in the plasma system 600, detects the occurrence of the instability, the impedance matching unit 402 is controlled immediately after, such as during a transition period of the RF signal 144, or simultaneously with controlling the RF generator 106 to change the state of the RF signal 144. In the example, by controlling the impedance matching unit 402 in such a manner, changes of the occurrence of the instability are reduced.

In an embodiment, the parameter sensor is not used in the plasma system 600.

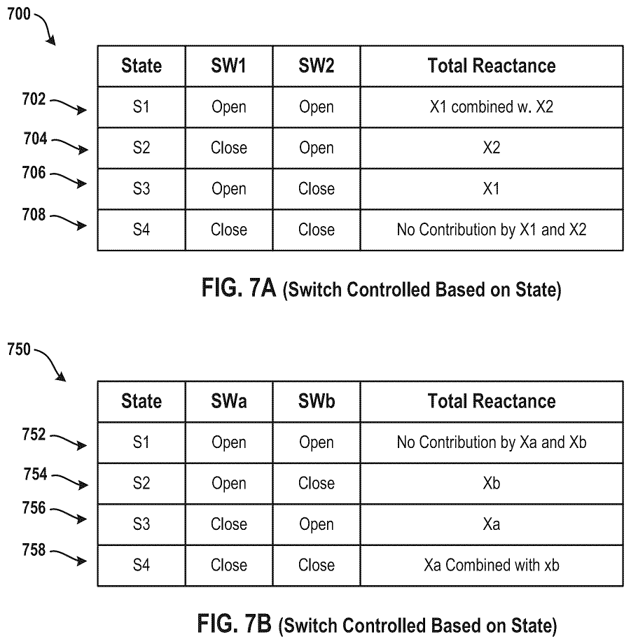

FIG. 7A is a diagram of an embodiment of a table 700 to illustrate correspondences between reactances of the impedance matching unit 402 (FIG. 6), positions of the switches SW1 and SW2, and states S1, S2, S3, and S4 of the RF signal 144 of FIG. 6. The correspondences are stored in the memory device 112 (FIG. 6). For example, the memory device 112 includes a correspondence 702 indicating that during the state S1 of the RF signal 144, to apply a combined reactance of the reactances X1 and X2 to the impedance of the RF signal 144, the switch SW1 is to be open and the switch SW2 is to be open. In the example, the memory device 112 includes a correspondence 704 indicating that during the state S2 of the RF signal 144, to apply the reactance X2 to the impedance of the RF signal 144, the switch SW1 is to be closed and the switch SW2 is to be open. Further in the example, the memory device 112 includes a correspondence 706 indicating that during the state S3 of the RF signal 144, to apply the reactance X1 to the impedance of the RF signal 144, the switch SW2 is to be closed and the switch SW1 is to be open. In the example, the memory device 112 includes a correspondence 708 indicating that during the state S4 of the RF signal 144, to not apply the reactances X1 and X2 to the impedance of the RF signal 144, the switch SW1 is to be closed and the switch SW2 is to be closed. When the reactances X1 and X2 are not applied to the RF signal 144, the impedance of the RF signal 144 is modified insubstantially.

The processor system 110 accesses one of the correspondences 702 through 708 from the table 700 to determine the positions of the switches SW1 and SW2 based on a reactance to be applied to the impedance of the RF signal 144. The reactance is identified by the processor system 110 based on one of the states S1 through S4 of the RF signal 144. The processor system 110 controls the switches SW1 and SW2 to achieve the positions to further achieve the reactance that is identified during the state of the RF signal 144.

FIG. 7B is a diagram of an embodiment of a table 750 to illustrate correspondences between reactances of the impedance matching unit 402 (FIG. 6), positions of the switches SWa and SWb, and the states S1, S2, S3, and S4 of the RF signal 144 of FIG. 6. The correspondences are stored in the memory device 112 (FIG. 6). For example, the memory device 112 includes a correspondence 752 indicating that during the state S1 of the RF signal 144, to not apply the reactances Xa and Xb to the impedance of the RF signal 144, the switch SWa is to be open and the switch SWb is to be open. When the reactances Xa and Xb are not applied to the impedance of the RF signal 144, the impedance of the RF signal 144 is modified insubstantially. In the example, the memory device 112 includes a correspondence 754 indicating that during the state S2 of the RF signal 144, to apply the reactance Xb to the impedance of the RF signal 144, the switch SWa is to be open and the switch SWb is to be closed. Further in the example, the memory device 112 includes a correspondence 756 indicating that during the state S3 of the RF signal 144, to apply the reactance Xa to the impedance of the RF signal 144, the switch SWa is to be closed and the switch SWb is to be open. In the example, the memory device 112 includes a correspondence 758 indicating that during the state S4 of the RF signal 144, to apply a combined reactance of the reactances Xa and Xb to the impedance of the RF signal 144, the switch SWa is to be closed and the switch SW2 is to be closed.

The processor system 110 accesses one of the correspondences 752 through 758 from the table 750 to determine the positions of the switches SWa and SWb based on a reactance to be applied to the impedance of the RF signal 144. The reactance is identified by the processor system 110 based on one of the states S1 through S4 of the RF signal 144. The processor system 110 controls the switches SWa and SWb to achieve the positions to further achieve the reactance that is identified during each state of the RF signal 144.

Broadly speaking, in a variety of embodiments, the controller is defined as electronics having various integrated circuits, logic, memory, and/or software that receive instructions, issue instructions, control operation, enable cleaning operations, enable endpoint measurements, and the like. The integrated circuits include chips in the form of firmware that store program instructions, digital signal processors (DSPs), chips defined as ASICs, PLDs, and/or one or more microprocessors, or microcontrollers that execute program instructions (e.g., software). The program instructions are instructions communicated to the controller in the form of various individual settings (or program files), defining the parameters, the factors, the variables, etc., for carrying out a particular process on or for a semiconductor wafer or to a system. The program instructions are, in some embodiments, a part of a recipe defined by process engineers to accomplish one or more processing steps during the fabrication of one or more layers, materials, metals, oxides, silicon, silicon dioxide, surfaces, circuits, and/or dies of a wafer.

Without limitation, in various embodiments, example systems to which the methods are applied include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that is associated or used in the fabrication and/or manufacturing of semiconductor wafers.

It is further noted that in some embodiments, the above-described operations apply to several types of plasma chambers, e.g., a plasma chamber including an inductively coupled plasma (ICP) reactor, a transformer coupled plasma chamber, conductor tools, dielectric tools, a plasma chamber including an electron cyclotron resonance (ECR) reactor, etc. For example, one or more RF generators are coupled to an inductor within the ICP reactor. Examples of a shape of the inductor include a solenoid, a dome-shaped coil, a flat-shaped coil, etc.

Some of the embodiments also relate to a hardware unit or an apparatus for performing these operations. The apparatus is specially constructed for a special purpose computer. When defined as a special purpose computer, the computer performs other processing, program execution or routines that are not part of the special purpose, while still being capable of operating for the special purpose.

One or more embodiments can also be fabricated as computer-readable code on a non-transitory computer-readable medium. The non-transitory computer-readable medium is any data storage hardware unit, e.g., a memory device, etc., that stores data, which is thereafter be read by a computer system. Examples of the non-transitory computer-readable medium include hard drives, network attached storage (NAS), ROM, RAM, compact disc-ROMs (CD-ROMs), CD-recordables (CD-Rs), CD-rewritables (CD-RWs), magnetic tapes and other optical and non-optical data storage hardware units. In some embodiments, the non-transitory computer-readable medium includes a computer-readable tangible medium distributed over a network-coupled computer system so that the computer-readable code is stored and executed in a distributed fashion.

Although the method operations above were described in a specific order, it should be understood that in various embodiments, other housekeeping operations are performed in between operations, or the method operations are adjusted so that they occur at slightly different times, or are distributed in a system which allows the occurrence of the method operations at various intervals, or are performed in a different order than that described above.

It should further be noted that in an embodiment, one or more features from any embodiment, described above, are combined with one or more features of any other embodiment, also described above, without departing from a scope described in various embodiments described in the present disclosure.

Although the foregoing embodiments have been described in some detail for purposes of clarity of understanding, it will be apparent that certain changes and modifications can be practiced within the scope of appended claims. Accordingly, the present embodiments are to be considered as illustrative and not restrictive, and the embodiments are not to be limited to the details given herein.

1. An impedance matching unit comprising:
an input port configured to be coupled to a radio frequency (RF) generator;
an output port configured to be coupled to a plasma chamber;
a connection point located between the input port and the output port;
a first reactive element coupled between the input port and the connection point;
a first switch coupled in parallel to the first reactive element;
a second reactive element coupled between the connection point and the output port; and
a second switch coupled in parallel to the second reactive element,
wherein the first and second switches are configured to operate to tune a reactance of the impedance matching unit.

2. The impedance matching unit of claim 1, wherein the first switch or the second switch or a combination thereof is configured to be controlled based on a change in stability of plasma within the plasma chamber.

3. The impedance matching unit of claim 2, wherein the first switch is configured to be in a first position or a second position and the second switch is configured to be in a first position or a second position, wherein the first switch is configured to switch from the first position to the second position when the stability is outside a predetermined range, wherein when the first switch switches from the first position to the second position, the stability is modified to be in the predetermined range.

4. The impedance matching unit of claim 3, wherein the second switch is configured to switch from the first position to the second position when the stability is outside the predetermined range, wherein when the second switch switches from the first position to the second position, the stability is modified to be in the predetermined range.

5. The impedance matching unit of claim 1, wherein the first switch or the second switch or a combination thereof is configured to be controlled based on a change in a state of an RF signal generated by the RF generator.

6. The impedance matching unit of claim 5, wherein the first switch is configured to be in a first position or a second position and the second switch is configured to be in a first position or a second position, wherein the first switch is configured to switch from the first position to the second position when the state of the RF signal changes from a first state to a second state.

7. The impedance matching unit of claim 6, wherein the second switch is configured to switch from the first position to the second position when the state of the RF signal changes from the first state to the second state.

8. The impedance matching unit of claim 5, wherein the state is determined based on a signal received from a sensor.

9. The impedance matching unit of claim 5, wherein the state is received within a recipe.

10. The impedance matching unit of claim 1, wherein the first reactive element is a capacitor or an inductor, and the second reactive element is a capacitor or an inductor.

11. An impedance matching unit comprising:
an input port configured to be coupled to a radio frequency (RF) generator;
an output port configured to be coupled to a plasma chamber;
a first connection point located between the input port and the output port;
a second connection point located between the input port and the output port;
a first reactive element coupled to the first connection point;
a first switch coupled in series to the first reactive element, wherein the first switch is coupled to a ground potential;
a second reactive element coupled to the second connection point; and
a second switch coupled in series to the second reactive element, wherein the second switch is coupled to the ground potential,
wherein the first and second switches are configured to operate to tune a reactance of the impedance matching unit.

12. The impedance matching unit of claim 11, wherein the first switch or the second switch or a combination thereof is configured to be controlled based on a change in stability of plasma within the plasma chamber.

13. The impedance matching unit of claim 12, wherein the first switch is configured to be in a first position or a second position and the second switch is configured to be in a first position or a second position, wherein the first switch is configured to switch from the first position to the second position when the stability is outside a predetermined range, wherein when the first switch switches from the first position to the second position, the stability is modified to be in the predetermined range.

14. The impedance matching unit of claim 13, wherein the second switch is configured to switch from the first position to the second position when the stability is outside the predetermined range, wherein when the second switch switches from the first position to the second position, the stability is modified to be in the predetermined range.

15. The impedance matching unit of claim 11, wherein the first switch or the second switch or a combination thereof is configured to be controlled based on a change in a state of an RF signal generated by the RF generator.

16. The impedance matching unit of claim 15, wherein the first switch is configured to be in a first position or a second position and the second switch is configured to be in a first position or a second position, wherein the first switch is configured to switch from the first position to the second position when the state of the RF signal changes from a first state to a second state.

17. The impedance matching unit of claim 16, wherein the second switch is configured to switch from the first position to the second position when the state of the RF signal changes from the first state to the second state.

18. The method of claim 15, wherein the state is determined based on a signal received from a sensor.

19. The impedance matching unit of claim 15, wherein the state is determined based on a recipe.

20. The impedance matching unit of claim 11, wherein the first reactive element is a capacitor or an inductor, and the second reactive element is a capacitor or an inductor.

21. A method comprising:
receiving a measurement of a parameter indicating stability of plasma within a plasma chamber;
determining a plurality of positions of a plurality of switches in an impedance matching unit based on the measurement of the parameter, wherein the impedance matching unit is located between a radio frequency (RF) generator and a plasma chamber, wherein each of the plurality of switches is in parallel with a corresponding one of a plurality of reactive elements of the impedance matching unit;
controlling the plurality of switches to be in the plurality of positions to achieve stability of the plasma and to tune a reactance of the impedance matching unit.

22. The method of claim 21, wherein the plurality of reactive elements are a plurality of capacitors or a plurality of inductors or a combination thereof.

23. The impedance matching unit of claim 1, wherein the reactance of the impedance matching unit is tuned to match an impedance of a load coupled to an output of the impedance matching unit with an impedance of a source coupled to an input of the impedance matching unit, wherein the first switch is configured to close or open and the second switch is configured to close or open to tune the reactance.

24. The impedance matching unit of claim 11, wherein the reactance of the impedance matching unit is tuned to match an impedance of a load coupled to an output of the impedance matching unit with an impedance of a source coupled to an input of the impedance matching unit, wherein the first switch is configured to close or open and the second switch is configured to close or open to tune the reactance.

25. The method of claim 21, wherein the reactance of the impedance matching unit is tuned to match an impedance of a load coupled to an output of the impedance matching unit with an impedance of a source coupled to an input of the impedance matching unit, wherein said controlling the plurality of switches includes closing or opening the first switch and open and closing or opening the second switch to tune the reactance.
